(19) United States
(12) Patent Application Publication
(10) Pub. No.: US 2015/0222218 A1
(43) Pub. Date: Aug. 6, 2015

(54) Solar Cell Panel Mount

(71) Applicant: NEMY, INC., Tokyo (JP)

(72) Inventor: Hiroshi Koyama, Tokyo (JP)

(73) Assignee: NEMY, INC., Tokyo (JP)

(21) Appl. No.: 14/593,442

(22) Filed: Jan. 9, 2015

(30) Foreign Application Priority Data
Feb. 3, 2014 (JP) 2014-018225

(51) Int. Cl. H02S 20/10; B23P 19/04; H01L 31/18

(52) U.S. Cl. CPC H02S 20/10; H01L 31/18; B23P 19/04

(57) ABSTRACT

The present invention provides a solar cell panel mount capable of fixing inclined column members at a predetermined inclination angle simply, stably for a long term, and methods of making and using thereof.

### TECHNICAL FIELD

The present invention relates to a solar cell panel mount for fixing a solar cell panel to a building rooftop or any other installation site at a predetermined inclination angle.

### BACKGROUND ART

Recently, importance of natural energy has been recognized and solar energy generation has come into widespread use. The solar energy generation is a distributed type energy generation system in which energy is generated using a solar cell panel fixed on a house roof, building rooftop or a predetermined side. For the purpose of increasing the photo-receiving efficiency of the solar cell panel, it is necessary to mount the solar cell panel at a predetermined inclination angle. In order to meet this necessity, a special mount is provided for fixing the solar cell panel thereto to adjust the height and inclination of the solar cell panel.

Adjustment of the inclination angle of the solar cell panel is generally performed by adjusting the height of a part (or a line) of a plurality of columns provided on the mount. As to this adjustment of the height of the columns, there are proposed various methods. For example, the following patent literature 1 discloses a method for adjusting the height of a column by providing a long hole that extends vertically in the column and moving a fixation bolt vertically in this long hole.

In addition, the patent literature 2 discloses a solar cell panel mount using a V-shaped column of which the height is adjusted by changing its opening angle. The following description is made in detail about a panel mount of this patent literature 2, with reference to the drawings .

FIG. 13 is a front view illustrating the structure of a mount column according to this conventional art. On a top of a base 2, a pair of column members of same length (a first column member 30 and a second column member 31) are mounted using base mounting hardwares 7. This pair of column members is mounted symmetrically in such a manner that each of the column members has an inclination angle of φ with respect to the vertical plane. Besides, upper ends of the V-shaped column members are fixed to a horizontal frame 4 by mounting hardwares 8a and 8b.

This V-shaped column according to the patent literature 2 is configured to have varying inclination angles φ. For the purpose of making the inclination angles vary, in a lower surface of the horizontal frame 4, a slide groove (not shown) is formed extending in the longitudinal direction and the mounting hardwares 8a and 8b are slidable in this groove in the longitudinal direction of the horizontal frame.

Further, the V-shaped column is configured to be able to turn at lower end mounting points (30b and 31b) and upper end mounting points (30a and 31a) of the first column member 30 and the second column member 31 (to be able to be fixed at various inclination angles) . This variation of the opening angle of the V-shaped column makes it possible to adjust the height from the upper surface of the base 2 to the horizontal frame 4, which is a feature of the structure of the panel mount of the patent literature 2.

### CITATION LIST

### Patent Literature

Patent Literature 1: Japanese Patent Application Publication No. 2009-302123
Patent Literature 2: Japanese Patent Application Publication No. 2012-54420

### SUMMARY OF THE INVENTION

### Technical Problem

Since the above-described V-shaped column can support the horizontal frame at two points by the single base, the numbers of bases and columns can be reduced advantageously as compared with an I-type column (single column that stands straight). This brings about a great merit that it is able to create a wide operation space under the solar cell panel.

Further, as the V-shaped column makes the opening angle variable, there is another merit that the distance between the support points of the V-shaped-column upper ends and the column height can be changed widely. Generally, the solar cell panel is mounted in various environments and it sometimes needs to be mounted in an especially narrow place or an uneven place. In such a situation, there is a great merit in use of the above-mentioned V-shaped column of which D (distance) and H (height) can be changed relatively flexibly.

However, in the conventional V-shaped column as disclosed in the patent literature 2, in order to make the inclination angles of the inclined column members variable, a one-point fixation method is generally adopted for fixing each column member at one fixation point by one bolt . This one-point fixation method has a problem that the column is likely to turn due to a force of gravity that acts on the inclined column members.

In fact, according to the experience of the inventors, they have found that when using the solar cell panel mount in which the inclined column members are each fixed at one point for a long term, tightening of the fixation bolts comes loose and the inclination angles of the column members are changed. This often causes problems of inclination of the solar cell panel toward an undesirable direction or breakage of the mount.

In order to solve these problems, a first object of the present invention is to provide a solar cell panel mount in which mounting hardwares are used to be able to fix the inclined column members at a predetermined inclination angle stably for a long term.

On the other hand, in the solar cell panel mount, the height of the space under the solar cell panel installed on the mount is often lower than the height of a human and a plurality of columns are mounted at random in the space, and therefore, the work space becomes inevitably narrow. In such a narrow work space, collaborative activity by plural workers is difficult and the mounting work is preferably performed by one person. Further, the work is often performed in an unstable posture and long-termwork imposes excess loads on the body of a worker . Therefore, the mounting work is desired to be performed simply and reliably in minimum time.

Then, the second object of the present invention is to provide means capable of, in an installation site of a solar cell panel mount as described above, performing the assembly work of the above-mentioned V-shaped column by a single worker, simply, quickly and reliably.

### Solution to Problem

The first aspect of the present invention is a solar cell panel mount comprising an upper frame body to mount a solar cell panel; and a plurality of columns, each upper end of the columns being fixed to the upper frame body using an upper part mounting hardware by an upper part fixation bolt, and each lower end of the columns being fixed to an upper part of abase using a base mounting hardware, wherein at least one of the columns is made up of a pair of inclined column members that are inclined at a predetermined inclination angle and are symmetric to each other with respect to a vertical line, the base mounting hardware to fix each of the inclined column members has a vertical part that is wide plate shaped and stands straight on an upper surface of the base, the vertical part has a pair of circular first bolt holes that are arranged to be symmetric to each other with respect to a width-directional center line and has a pair of curved long groove shaped second bolt holes that are formed along circular arcs whose centers are the respective first bolt holes and are symmetric to each other, and each of the pair of the inclined column members is fixed at two points including one of the first bolt holes and a corresponding one of the second bolt holes by lower part fixation bolts.

The second aspect of the present invention is an assembly method for the solar cell panel mount according to the first aspect, the assembly method comprising the steps of: making the lower part fixation bolts pass through the first bolt hole and the second bolt hole to temporarily fix each of the inclined column members; fitting a positioning jig to upper part mounting hardwares of the pair of the inclined column members to adjust an open width between tip ends of the pair of the inclined column members; tightening the lower part fixation bolts that pass through the base mounting hardware to fix the inclination angle of the inclined column members; and removing the positioning jig and fixing the upper part mounting hardwares to the upper frame body by upper part fixation bolts.

The third aspect of the present invention is the assembly method for the solar cell panel mount according to the second aspect, wherein the positioning jig has a band plate shaped member in which an inverted U shaped notch is formed near each of both ends in a longitudinal direction of the band plate shaped plate, and the inverted U shaped notch is sized to make the upper part fixation bolt fit therein.

The fourth aspect of the present invention is the assembly method for the solar cell panel mount according to the second aspect, wherein the positioning jig has a band plate shaped member having a pair of bolt holes formed around respective tip ends in a longitudinal direction of the band plate shaped member, the band plate shaped member is divided at a center in the longitudinal direction into a pair of band pieces, a hinge is attached to one-side side surfaces of the divided band pieces so that the band plate shaped member is able to bend by the hinge, and the pair of bolt holes are spaced away from each other by a predetermined distance when the band plate shaped member is not bent.

The fifth aspect of the present invention is the assembly method for the solar cell panel mount according to the second aspect, wherein the positioning jig has a band plate shaped member having a bolt hole formed near one end part in a longitudinal direction of the band plate shaped member and an inverted U shaped notch formed in a one-side side surface near an opposite end part of the band plate shaped member, the inverted U shaped notch is sized to make the lower part fixation bolt fit therein, and a distance d between a center of the inverted U shaped notch and a center of the bolt hole meets an equation: d=D(l/L), where

D: a distance between centers of the upper part bolt holes of the pair of the inclined column members of which the inclination angle is fixed,

l: a distance between an intersection point of width-directional center lines of the pair of inclined column members of which the inclination angle is fixed and a center of an upper bolt hole out of two bolt holes formed at a lower part of one of the inclined column members, and

L: a distance between an intersection point of width-directional center lines of the pair of inclined column members of which the inclination angle is fixed and a center of a bolt hole formed at an upper part of one of the inclined column members.

In the assembly method for the solar cell panel mount of the present invention, when performing positioning using the positioning jig of the fourth aspect, the upper part fixation bolts are made to pass through the bolt holes at both ends of the positioning jig of the fourth aspect while the positioning jig is bent to temporarily fix tip ends of the positioning jig to upper parts of the pair of the inclined column members, and while the upper part fixation bolts used in temporary fixation are released, a bent part of the positioning jig is lifted up to make the positioning jig straight thereby to adjust the open width between the tip ends of the pair of the inclined column members and the inclination angle.

In the assembly method for the solar cell panel mount of the present invention, when performing positioning using the positioning jig of the fifth aspect, an upper bolt out of the lower part fixation bolts fit in one of the pair of the inclined column members is made to pass through the bolt hole formed at the one end of the positioning jig of the fifth aspect, and while the opposite end of the positioning jig is free, the one end of the positioning jig is temporarily fixed to the one inclined column member, and the inverted U shaped notch at the opposite end of the positioning jig is fit in a space between an opposite inclined column member and a nut for an upper bolt of the lower part fixation bolts fit in the opposite inclined column member thereby to adjust the open width between tip ends of the pair of the inclined column members and the inclination angle.

### Technical Advantage of the Invention

According to the present invention, as the V shaped column capable of adjusting the height by changing the inclination angle is used as a column for solar cell panel mount, it is possible to fix the bottom parts of the inclined column members firmly to mounting hardwares at two support points while keeping the inclination angle of each of the inclined column members variable. With this structure, it is also possible to improve the endurance of the mount using the V-shaped column greatly.

Further, according to the assembly method of the solar cell panel mount of the present invention, the mounting work of the V-shaped column to be performed in an installation site is able to be performed simply and quickly by one person, which makes it possible to greatly reduce the physical load on the worker.

### BRIEF DESCRIPTION OF THE DRAWINGS

FIG. 1 is a perspective view of a solar cell panel mount according to one embodiment of the present invention;

FIG. 2 is a side view of the solar cell panel mount according to the embodiment of the present invention;

FIG. 3 provides views each illustrating the structure of a V-shaped column used in the embodiment of the present invention;

FIG. 4 provides views each illustrating a first example of the shape of a base mounting hardware used in the present invention;

FIG. 5 provides views each illustrating a second example of the shape of the base mounting hardware used in the present invention;

FIG. 6 provides explanatory views of the work procedure of an assembly method of the solar cell panel mount according to the present invention;

FIG. 7 is a perspective view illustrating a first example of a positioning jig used in the present invention;

FIG. 8 provides views each illustrating a second example of the positioning jig used in the present invention;

FIG. 9 provides explanatory views of a method of use of the positioning jig of the second example;

FIG. 10 provides views each illustrating a third example of the positioning jig used in the present invention;

FIG. 11 is a view illustrating a fourth example of the positioning jig used in the present invention;

FIG. 12 provides views each illustrating a fifth example of the positioning jig used in the present invention; and

FIG. 13 is a front view illustrating the structure of the column for solar cell panel mount according to the conventional art.

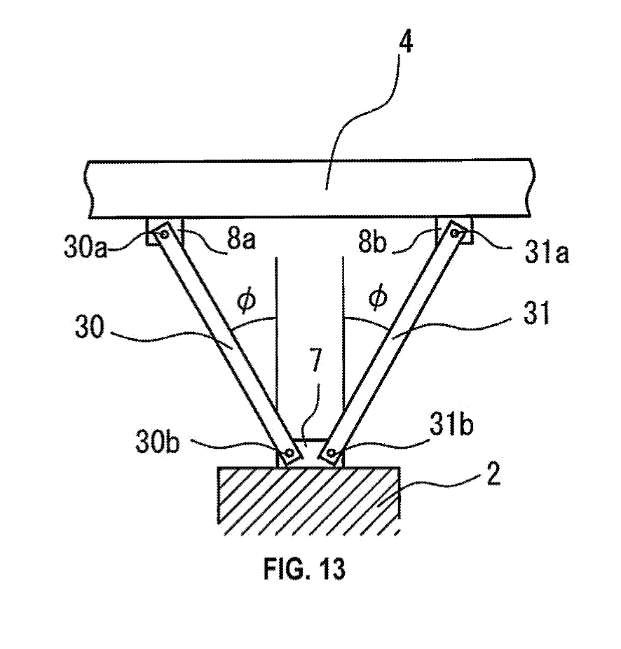

### REFERENCE NUMERALS

1 solar cell panel
2 base
3 column
4 horizontal frame
5 vertical frame
6, 6a, 6b ; inclined column member
7 base mounting hardware
8, 8a, 8b upper part mounting hardware
9 horizontal part
10 vertical part
11 anchor bolt hole
12, 12a, 12b first bolt hole
13, 13a, 13b second bolt hole
14 lower part fixation bolt
15 positioning jig
16 upper part fixation bolt
17 band plate shaped member
18, 18a, 18b inverted U-shaped notch
19 anchor bolt
20 bolt hole
21 band plate shaped member
22a, 22b band shaped piece
23 hinge
24 bar member
25, 25a, 25b fin member
26 Ω shaped groove
27 movable member
28 piece member
29 connecting member
30 first column member
31 second column member
30a, 31a upper end mounting point
30b, 31b lower end mounting point
32 band plate shaped member

### DESCRIPTION OF EMBODIMENTS

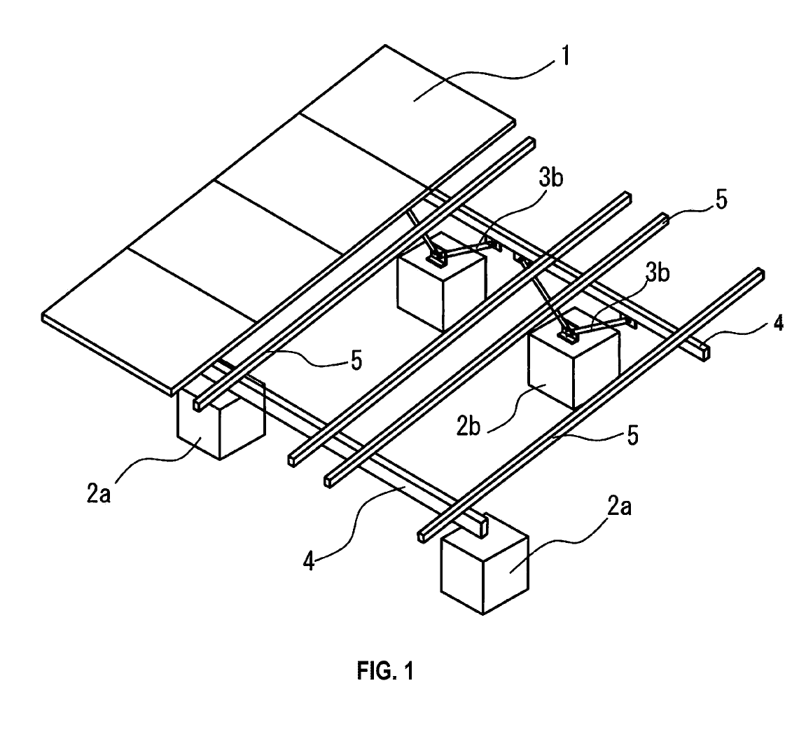

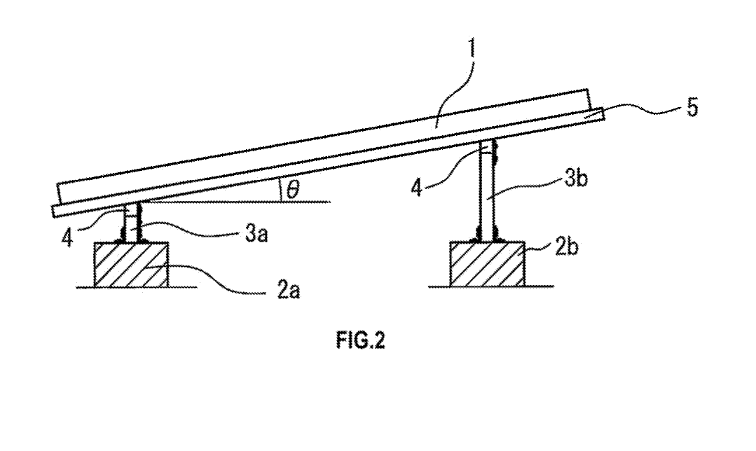

With reference to the drawings, preferable embodiments of the present invention will be described below. FIG. 1 is a perspective view of a solar cell panel mount according to an embodiment of the present invention and FIG. 2 is a side of the mount. This mount is configured of an upper frame body (including horizontal frames 4 and vertical frames 5) to mount the solar cell panel 1 on the upper surface thereof and a plurality of or plural lines of columns 3 mounted on bases 2.

As illustrated in FIG. 2, the columns 3 have low columns 3a provided to the left in FIG. 2 (base 2a side) and high columns 3b provided to the right (base 2b side) . With this difference in height, the upper frame body and the solar cell panel 1 mounted thereon are inclined at an inclination angle θ with respect to the horizontal plane.

The upper frame body is configured of the horizontal frames 4 that extend in a direction approximately orthogonal to the inclination direction of the solar cell panel 1 and the vertical frames 5 mounted thereon. Mounting of each vertical frame 5 to the horizontal frames 4 is not limited to any method, and may be performed by using mounting hardwares (brackets), directly fastening with volt or screw, or any other method. Further, the shape and structure of the upper frame body are not limited to those in the present embodiment.

As illustrated in FIG. 1, the columns 3a at the inclination front side are single columns (I type) and columns 3b at the inclination rear side are V-shaped columns formed of two columns open above. In the mount of the present invention, these V-shaped columns may be a part of the plural columns (for example, in a line) or all the columns may be V-shaped columns.

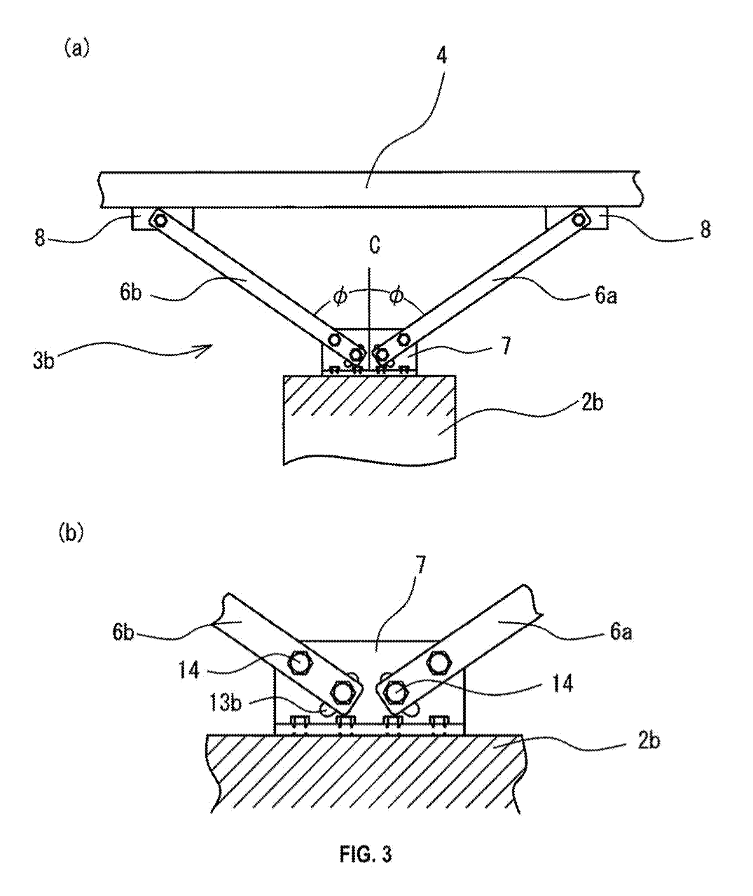

FIG. 3 provides views each illustrating the structure of the V-shaped columns, and in FIG. 3, (a) is a front view and (b) is a partially enlarged view of (a) . These V-shaped columns are such that a pair of inclined column members 6a and 6b are provided inclined symmetrically with respect to the center vertical line C at an inclination angle φ. At the lower ends of these both inclined column members 6a and 6b are fixed to the base 2b using base mounting hardwares 7, and upper ends are fixed to the horizontal frame 4 using upper part mounting hardwares 8. Mounting of the inclined column members 6a and 6b to the base mounting hardwares 7 is performed using lower part fixation bolts 14.

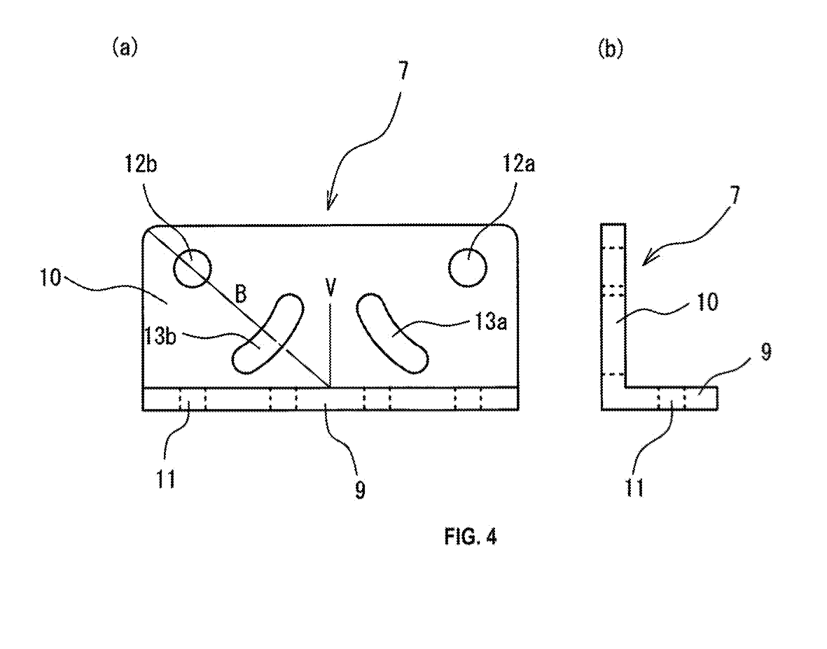

The mount of the present invention has features in the mounting method of the inclined column members 6 of this V-shaped column and the shape and structure of the base mounting hardware for fixing them. FIG. 4 provides views illustrating a first example of the shape of a base mounting hardware used in the present invention. In FIG. 4, (a) is a front view and (b) is a side view. This base mounting hardware 7 is made of a plate member that is wide in breadth and has an L-shaped cross section, having a horizontal part 9 and a vertical part 10.

This vertical part 10 has a function of mounting the inclined column member 6 and may be any plate member mounted on the upper surface of the base 2 and stands straight thereon. Mounting of this part is not limited to any method and may be performed by mounting it to a horizontal part of the L shape as shown in the example of FIG. 4 (by passing an anchor bolt through a bolt hole 11) or mounting it to a horizontal part of the inversed T shape. Or, the vertical member may extend to make its lower part embedded in the base or mounted to the side surface of the base.

The vertical part 10 has two circular first bolt holes 12a and 12b and two second bolt holes 13a and 13b of curved long groove shape spaced by a predetermined distance from the first bolt holes 12a and 12b, respectively. These second bolt holes 13a and 13b are formed extending on circular arcs having the first bolt holes 12a and 12b as center, respectively. With this structure, even when inclined column members 6a and 6b are turned around the first volt holes 12a and 12b, the fixation bolts passing through the second bolt holes 13a and 13b are able to move in the long grooves . Therefore, even when the inclination angle of the inclined column members 6 is changed, it is possible to support them at two support points.

Further, the two first bolt holes 12a and 12b and the two second bolt holes 13a and 13b are arranged symmetrically with respect to the vertical line V at the horizontally center position of the vertical part 10. With this structure, it is possible to mount the paired inclined column members 6 of the V-shaped column to the one base mounting hardware axially symmetrically.

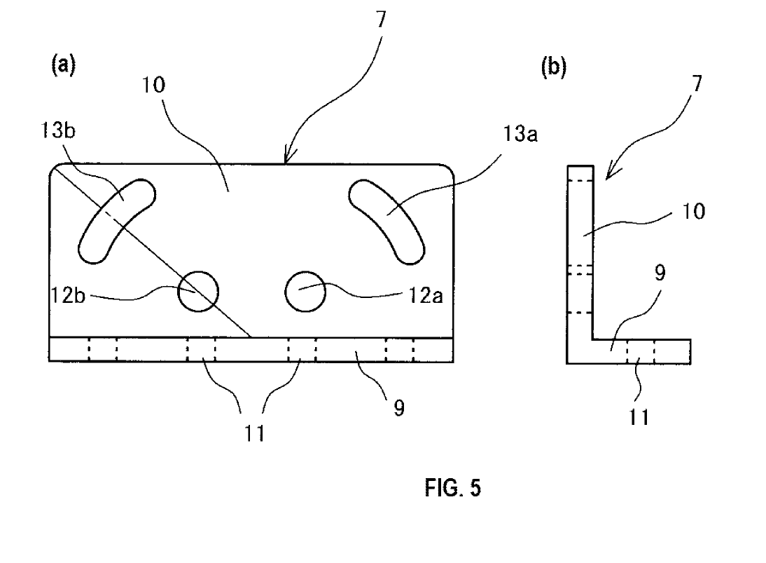

In the example of FIG. 4, the first bolt 12b is provided at the left upper side and the second bolt hole 13b is provided at the right bottom side on the diagonal line B of the vertical part 10. However, positional relation of them may be inversed. FIG. 5 provides views each illustrating a second example of the shape of the base mounting hardware used in the present invention. In FIG. 5, (a) is a front view and (b) is a side view. In this case, the second bolt hole 13b of long groove shape is provided at the left upper side and the circular first bolt hole 12b is provided at the right bottom side. Like in the example of FIG. 4, the fixation bolt passing through the second bolt 13 is able to move within the long groove, and therefore, the inclined column members 6 are able to be fixed at various inclination angles around the first bolt hole 12.

With use of the above-described mounting hardware of the present invention, it is possible to fix the V-shaped column at two support points while keeping the inclination angle of the inclined column members variable. This makes it possible to remarkably improve the resistance against the rotational stress on the inclined column members as compared with the conventional case of single support point. Therefore, it is possible to prevent the trouble that the fixation bolts of the inclined column members come into loose to cause a change in the inclination angle of the column members, thereby allowing significant improvement of the endurance of the mount.

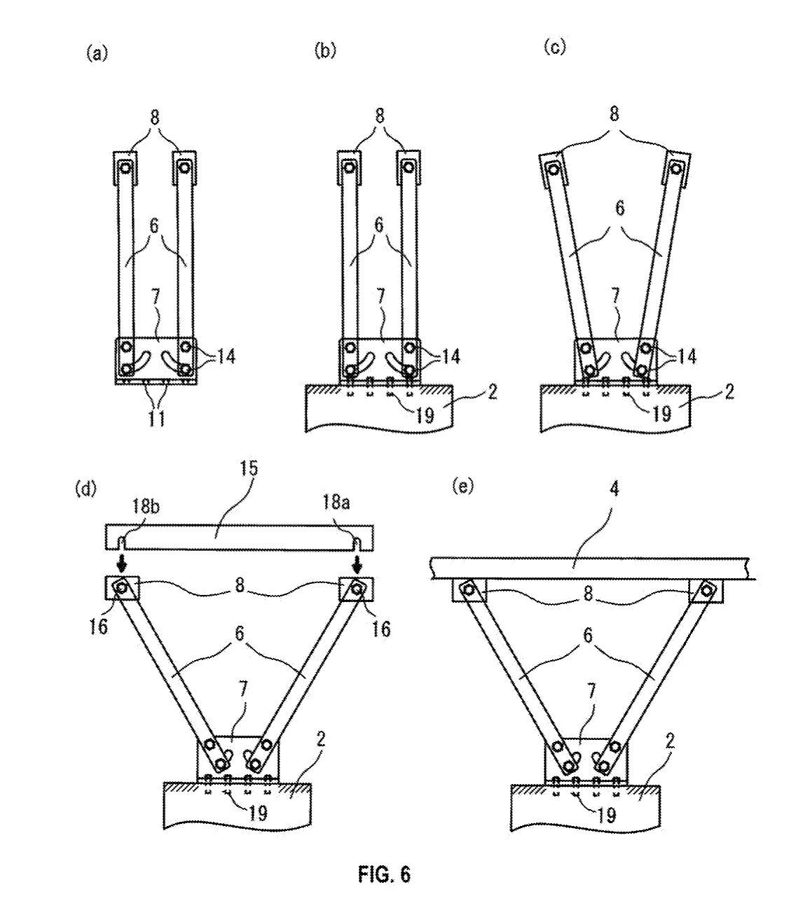

The following description is made, with reference to the drawings of the embodiments, about an assembly method of the solar cell panel mount of the present invention. FIG. 6 is an explanatory view illustrating the operational procedure of the assembly method of the present invention. This assembly method includes the following steps (S-1) to (S-8).

### (S-1)

The above-described inclined column members 6 are prepared in a pair, in each of which two bot holes are formed at the predetermined positions near the lower end and one bolt hole is formed at a predetermined position near the upper end. At the lower part of each of the paired inclined column members 6, the base mounting hardware 7 is temporarily fastened and at the upper part thereof, the upper part mounting hardware 8 is temporarily fastened thereto (see (a) in FIG. 6) . Temporary fixation is performed by using a normal fixation bolt and the bolt has only to be tightened loosely. This hardware mounting work is performed within a factory before shipment. This work step is called “mounting hardware temporary fixation step”.

### (S-2)

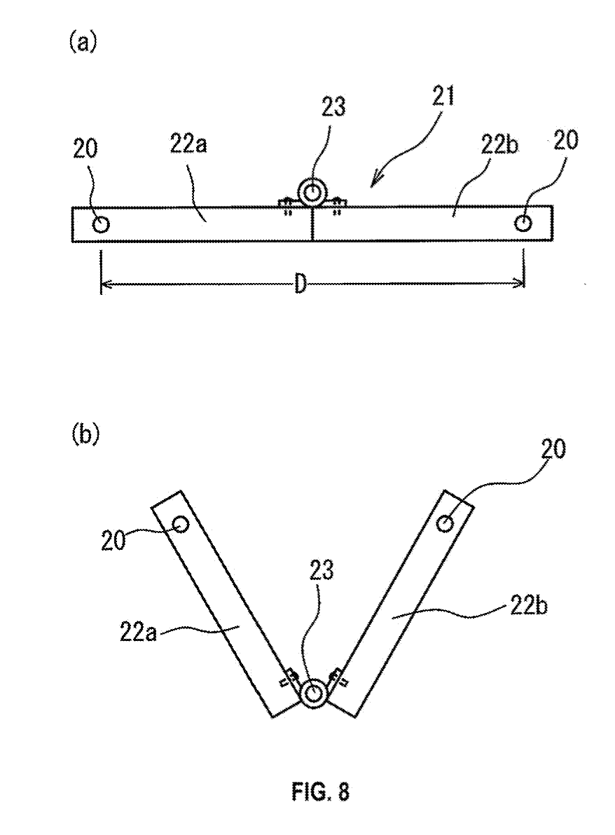

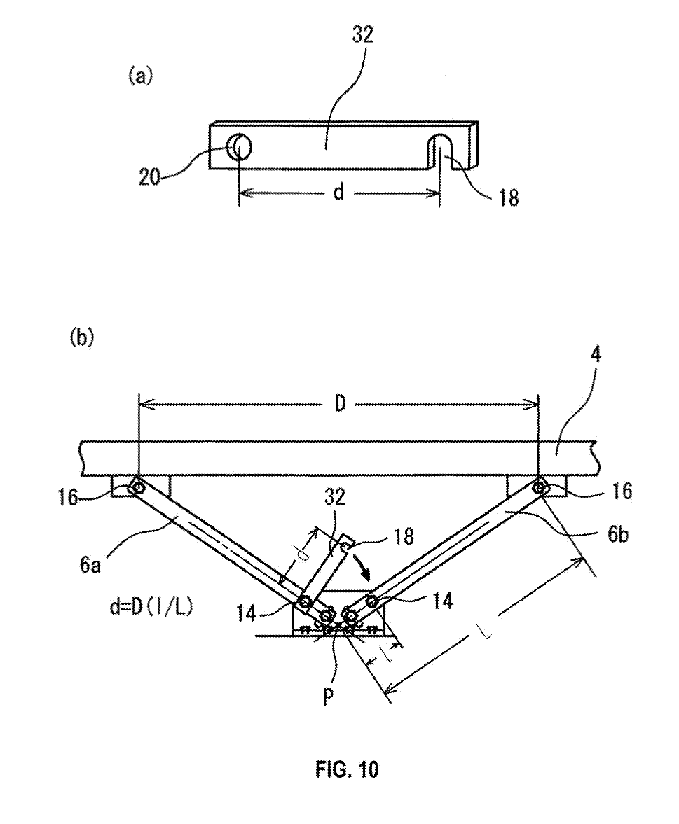

A positioning jig 15, which is used to adjust the open width between the upper ends of the paired inclined column members 6, is temporarily fixed to one or both of the inclined column members, when necessary (this work step is called “positioning jig 15 temporary fixation step”) . As to whether this positioning jig 15 temporary fixation step is needed or not, it depends on the structure of the jig and in a second example (FIG. 8) and a third example (FIG. 10), which are described later, the positioning jig 15 temporary fixation step is required, but is not required as with another jig.

### (S-3)

Then, the paired inclined column members 6 with the base mounting hardware 7 (and positioning jig 15) fixed thereto are conveyed to an installation site in a state where both of the members are parallel to each other (conveyance step).

### (S-4)

Then, the base mounting hardware 7 to which the inclined column members 6 are fixed temporarily is mounted on the base 2 for the solar cell panel mount (base mounting step).

In this embodiment, an anchor bolt 19 embedded in advance in the base 2 is made to pass through an anchor bolt hole 11 formed in the horizontal part 9 of the base mounting hardware 7 and the nut is tightened up thereby to mount the base mounting hardware 7 on the base 2 (see (b) in FIG. 6). However, mounting is not limited to this method of the above-mentioned example.

### (S-5)

Then, the lower part fixation bolts 14 used to temporarily fix the paired inclined column members 6 to the base mounting hardware 7 are released to make the inclination angle of the inclined column members 6 variable (inclination angle varying step, see (c) in FIG. 6). That is, the bolts may be released to the extent that the inclination angle of the inclined column members 6 can be changed by human power.

### (S-6)

Next, the positioning jig 15 is used to adjust the inclination angle and the open width between the tip ends of the paired inclined column members 6 (positioning step).

In this embodiment, the positioning jig 15 is mounted on each of the paired upper fixation bolts 16 to which the upper mounting hardwares 8 are fixed temporarily, and the distance between them is kept at a predetermined value thereby to adjust the inclination angle of the inclined column members 6 (see (d) in FIG. 6).

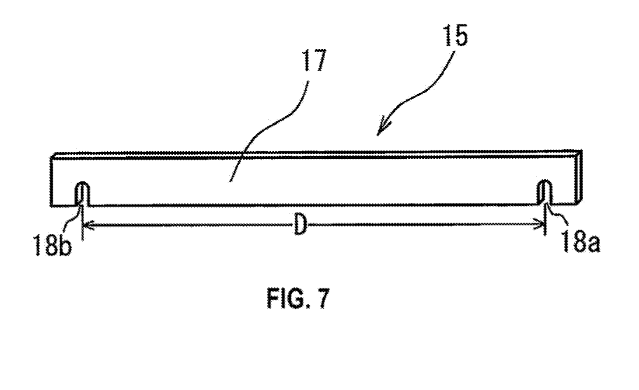

FIG. 7 is a perspective view illustrating a first example of the positioning jig 15 used in the present invention. The body of this jig 15 is made of a band plate shaped member 17, in which a pair of inverted U-shaped notches 18a and 18b are formed near the longitudinal ends of the band plate shaped member 17 and in its one-side side surface (one side surface in the width direction). The width of each notch may be any value as far as the upper part fixation bolt 16 can be fit therein. And, the inverted U shaped notches 18a and 18b are formed to have a distance between them kept at a predetermined value D.

Here, the positioning jig 15 may be any jig as far as it has a function of retaining the distance between the paired upper prat fixation bolts 16 at a predetermined value, and its shape and structure are not limited to those in this example. They may be embodied in various forms as illustrated in each example described later.

The positioning jig 15 in FIG. 7 has a merit that it can be easily mounted on or demounted from the upper part fixation bolts 16. That is, in the jig of this embodiment, an enough space is formed by backing off the nut greatly from the tightening surface, the band plate shaped member 17 is inserted into this space and the bolts are fit in the inverted U shaped notches 18a and 18b thereby to mount the jig 15. In addition, in order to remove this jig 15, this can be performed only by lifting the band plate shaped member 17 up (and releasing the nut when necessary) .

Further, adjustment of the inclination angle of the inclined column members 6 may be performed by making the positioning jig 15 mounted on the upper part fixation bolts 16 horizontal. With this process, the paired inclined column members 6 become symmetric with respect to the vertical line.

### (S-7)

Then, while the inclination angle of the paired inclined column members 6 is adjusted, the lower part fixation bolts 14 that pass through the base mounting hardware 7 are tightened up thereby to fix the inclination angle of the inclined column members 6 (inclination angle fixation step).

### (S-8)

After that, the positioning jig 15 is removed as needed and the upper part mounting hardwares 8 are affixed to the lower surface of the upper part frame body (the horizontal frame 4 in this embodiment) (upper part frame body affixing step, see (e) in FIG. 6) . Affixing to the horizontal frame is not limited to this.

In this step, as to whether it is necessary to remove the positioning jig 15 or not, it depends on the structure of the jig and removal of the positioning jig 15 is not required in the second example (FIG. 8) and the third example (FIG. 10), but a jig is to be removed generally.

Next description is made about another example of the positioning jig used in the above-described assembly method.

FIG. 8 provides perspective views each illustrating a second example of the positioning jig used in the present invention. The main body of this jig is made of a band plate shaped member 21 having a pair of bolt holes 20 near the tip ends in the longitudinal direction. This member is cut at the center in the longitudinal direction and divided into a pair of band pieces 22a and 22b, and a hinge 23 is attached to a one-side side surface of each cut part (one of side surfaces in the width direction).

With this process, the band pieces 22a and 22b are provided such that the positioning jig (band plate shaped member 21) is able to be bent by the hinge 23 when their cut surfaces are facing each other. In FIG. 8, (a) illustrates the both band pieces that are aligned straight and (b) illustrates the both band pieces that are formed into a bent member. In addition, the distance between the paired bolt holes is configured to be a predetermined distance D when the both band pieces are aligned straight (when the positioning jig (band plate shaped member 21) is not bent).

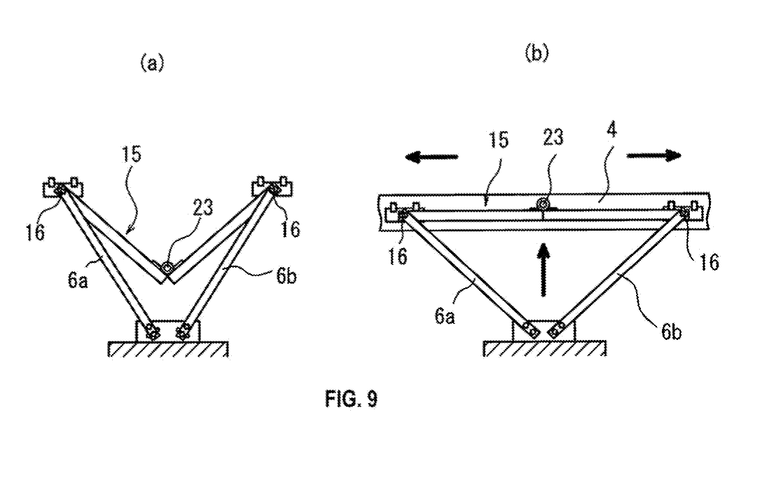

Next description is made about a positioning method using a positioning jig of this second example in the assembly method of the present invention. FIG. 9 is an explanatory view of the method of using the positioning jig of the second example. In the positioning jig temporary fixation step (S-2) of the assembly method of the present invention described above, while the positioning jig is bent, upper part fixation bolts 16 are inserted into the bolt holes 20 at the respective ends of the jig to temporarily fix the tip ends of the jig to the upper parts of the paired inclined column members 6a and 6b (see (a) in FIG. 9).

Then, in the positioning step (S-5), the upper part fixation bolts 16 used in temporary fixation are released, and then, the bent part of the bent positioning jig is lifted up so that the bent positioning jig becomes straight (see (b) in FIG. 9). With this process, the open width between the tip ends of the paired inclined column members 6a and 6b becomes a predetermined value (distance D between the paired upper part bolt holes). The inclination angle of the paired inclined column members 6a and 6b can be adjusted appropriately by adjusting the positioning jig to be horizontal.

FIG. 10 is a view illustrating a third example of the positioning jig used in the present invention. The main body of this jig is made of a band plate shaped member 32, in which a bolt hole 20 is formed near one end part in the longitudinal direction of the band plate shaped member 32 and an inverted U shaped notch 18 is formed in a one-side side surface near the other end part (one side surface in the width direction). The inverted U shaped notch 18 has such a size that the lower part fixation bolt 14 can be fit therein. The distance d between the center of the inverted U shaped notch 18 and the center of the bolt hole 20 is configured to meet the following expression (1).

d=D(l/L) (1)

where
D: a distance between the centers of the upper part bolt holes of the respective inclined column members of which the inclination angle is fixed
l: a distance from the intersecting point P of the center lines in the width direction of the paired inclined column members 6 of which the inclination angle is fixed to the center of the upper bolt hole out of the two bolt holes formed in the lower part of one inclined column member 6
L: a distance from the intersecting point P of the center lines in the width direction of the paired inclined column members 6 of which the inclination angle is fixed to the center of the bolt hole formed in the upper part of one inclined column member 6

Next description is made about the positioning method using a positioning jig of the third example in the assembly method of the present invention. In FIG. 10, (b) is an explanatory view of the method of using the positioning jig of the third example.

First, in the positioning jig temporary fixation step (S-2), an upper bolt out of the two lower part fixation bolts 14 of one of the inclined column members 6 (6a or 6b) is made to pass through the bolt hole 20 at an end of the positioning jig and one end of the positioning jig is temporarily fixed to one of the inclined column members 6 (6a or 6b) while the other end of the jig is free (the lower part fixation bolt 14 is not fit in the inverted U shaped notch 18) (see (b) in FIG. 10).

Then, in the positioning step (S-5), in the other inclined column member 6 (the other one of the inclined column members to which the jig is not temporarily fixed), a nut of an upper one of the two lower part fixation bolts 14 is backed off greatly and the positioning jig is inserted into the space between the nut and the inclined column member (6a or 6b) so that the lower part fixation bolt 14 is fit in the inverted U shaped notch 18 (see (b) in FIG. 10).

With this process, the open width between the tip ends of the paired inclined column members 6a and 6b becomes a desired value (the distance between the paired upper bolt holes becomes D).

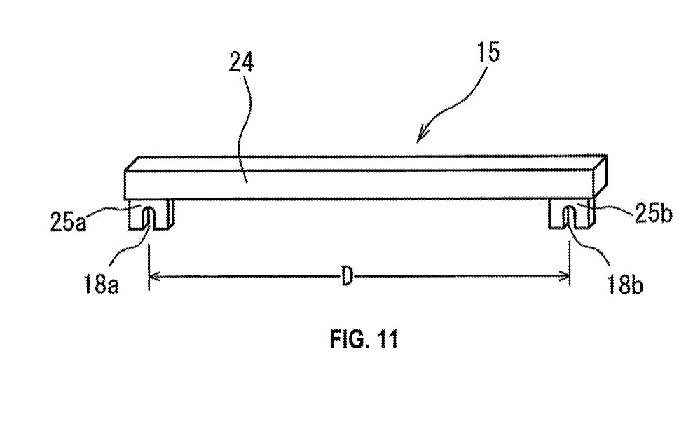

FIG. 11 is a perspective view illustrating a fourth example of the positioning jig used in the present invention. The main body of this jig is made of a bar member 24 of a square shaped cross section . This bar member 24 has a pair of square fin members 25a and 25b near both ends in the longitudinal direction, respectively, and the square fin members 25a and 25b jut from the respective side surfaces. In the tip end centers of the both fin members 25a and 325b, inverted U shaped notches 18a and 18b are formed to have a size that the upper part fixation bolts 16 can be fit therein. The distance between the centers of the both notches 18a and 18b is configured to be a desired value (the distance between the paired upper part bolt holes becomes D).

The method of using the positioning jig of the fourth example is the same as that of the positioning jig of the first example . However, it has an advantageous feature that it is possible to change the distance between the centers of the inverted U shaped notches 18a and 18b by changing the position to attach one of the fin members (25a or 25b) to the bar member 24.

The V-shaped column has a feature that the height is variable. However, as the length of the inclined column members 6 is fixed, if the height is to be changed, it is necessary to configure the distance between the upper ends of the paired inclined column members 6 to be set to any value. Therefore, the distance between the paired inverted U shaped notches 18a and 18b of the positioning jig needs to be variable .

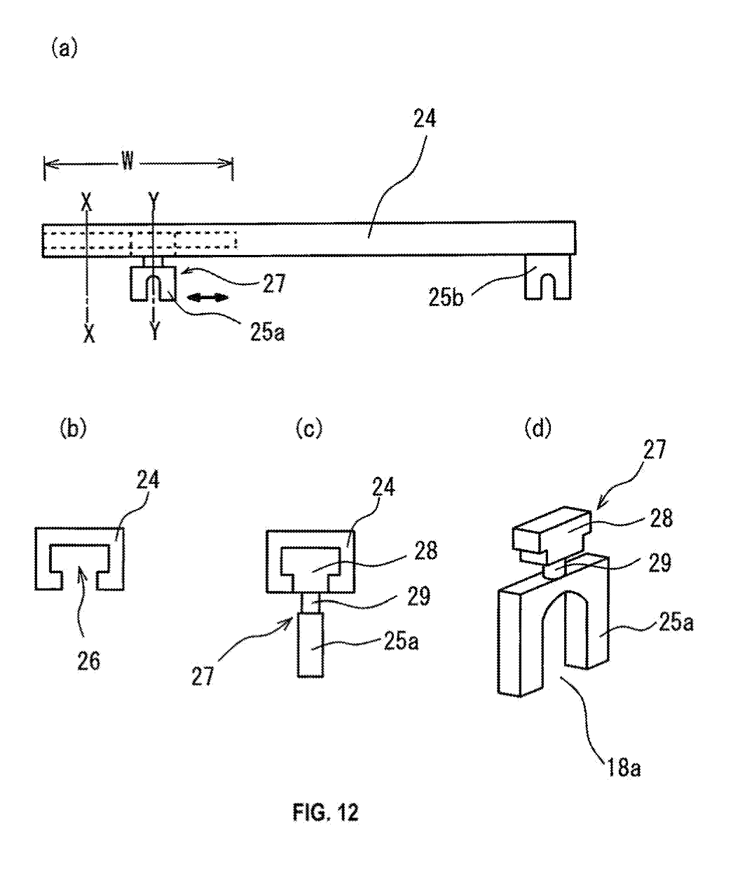

FIG. 12 provides views each illustrating a fifth example of the positioning jig used in the present invention. In FIG. 12, (a) is a front view, (b) is a cross sectional view taken along X-X in (a), (c) is a cross sectional view taken along Y-Y in (a), and (d) is a perspective view of a movable member.

This jig also has a pair of square fin members 25a and 25b jutting from the respective side surfaces near both ends in the longitudinal direction, like the positioning jig of the fourth example. However, the jig of this example is different from that of the fourth example in that one fin member 25a is movable in the longitudinal direction of the bar member 24.

As illustrated in the drawings, a Ω shaped groove 26 is formed within a predetermined area W at one end in the longitudinal direction of the bar member 24. The Ω shaped groove 26 has a cross section of fixed size and is open in the lower surface. In this Ω shaped groove 26, a movable member 27 is arranged to be slidable in the longitudinal direction. This movable member 27 is made of, as illustrated in FIG. 12(d), a piece member 28, the fin member 25a and a connecting member 29 for connecting the fin member 25a to the piece member 28. The outer shape of the cross section of the piece member 28 is formed to conform to the inner shape of the cross section of the Ω shaped groove 26 with such a clearance as makes the piece member 28 slidable therein.

With this structure, it is possible to make the distance between the centers of the paired inverted U shaped notches 18a and 18b of the positioning jig variable . Here, in the positioning work, it is preferable to prepare any stopping member for stopping the movable member 27 at a predetermined position to prevent sliding. Such a stopping member is realized by a method of forming a spiral groove in the connecting member 29, arranging a tightening ring to fit therein (not shown) and pressing the lower surface of the bar member 24 by this tightening ring to stop the movable member 27, or a method of arranging a coil spring (not shown) around the outer circumference of the connecting member 29 and using a pressing force to press the lower surface of the bar member 24 by the upper surface of the coil spring to stop the movable member 27.

According to the assembly method of a solar cell panel mount of the present invention described up to this point, it is possible to perform the mounting work to mount the V-shaped column on the base by one person. The mounting of the V-shaped column can be performed only by using the easily removable positioning jig and tightening up or releasing the nuts. Therefore, it is possible to perform the work even in a narrow space, quickly and simply, thereby greatly reducing the physical load on the worker.

1. A solar cell panel mount comprising an upper frame body to mount a solar cell panel; and a plurality of columns, each upper end of the columns being fixed to the upper frame body using an upper part mounting hardware by an upper part fixation bolt, and each lower end of the columns being fixed to an upper part of a base by a base mounting hardware, wherein
at least one of the columns is made up of a pair of inclined column members that are inclined at a predetermined inclination angle and are symmetric to each other with respect to a vertical line,
the base mounting hardware to fix each of the inclined column members has a vertical part that is wide plate shaped and stands straight on an upper surface of the base,
the vertical part has a pair of circular first bolt holes that are arranged to be symmetric to each other with respect to a width-directional center line and has a pair of curved long groove shaped second bolt holes that are formed along circular arcs whose centers are the respective first bolt holes and are symmetric to each other, and
each of the pair of the inclined column members is fixed at two points including one of the first bolt holes and a corresponding one of the second bolt holes by lower part fixation bolts.

2. An assembly method for the solar cell panel mount according to claim 1, the assembly method comprising the steps of:
making the lower part fixation bolts pass through the first bolt hole and the second bolt hole to temporarily fix each of the inclined column members;
fitting a positioning jig to upper part mounting hardwares of the pair of the inclined column members to adjust an open width between tip ends of the pair of the inclined column members;
tightening the lower part fixation bolts that pass through the base mounting hardware to fix the inclination angle of the inclined column members; and
removing the positioning jig and fixing the upper part mounting hardwares to the upper frame body by upper part fixation bolts.

3. The assembly method according to claim 2, wherein the positioning jig has a band plate shaped member in which an inverted U shaped notch is formed near each of both ends in a longitudinal direction of the band plate shaped plate, and the inverted U shaped notch is sized to make the upper part fixation bolt fit therein.

4. The assembly method according to claim 2, wherein
the positioning jig has a band plate shaped member having a pair of bolt holes formed around respective tip ends in a longitudinal direction of the band plate shaped member,
the band plate shaped member is divided at a center in the longitudinal direction into a pair of band pieces,
a hinge is attached to one-side side surfaces of the divided band pieces so that the band plate shaped member is able to bend by the hinge, and
the pair of bolt holes are spaced away from each other by a predetermined distance when the band plate shaped member is not bent.

5. The assembly method according to claim 2, wherein
the positioning jig has a band plate shaped member having a bolt hole formed near one end part in a longitudinal direction of the band plate shaped member and an inverted U shaped notch formed in a one-side side surface near an opposite end part of the band plate shaped member, the inverted U shaped notch is sized to make the lower part fixation bolt fit therein, and a distance d between a center of the inverted U shaped notch and a center of the bolt hole meets an equation: d=D(l/L), where
D: a distance between centers of the upper part bolt holes of the pair of the inclined column members of which the inclination angle is fixed,
l: a distance between an intersection point of width-directional center lines of the pair of inclined column members of which the inclination angle is fixed and a center of an upper bolt hole out of two bolt holes formed at a lower part of one of the inclined column members, and
L: a distance between an intersection point of width-directional center lines of the pair of inclined column members of which the inclination angle is fixed and a center of a bolt hole formed at an upper part of one of the inclined column members.

6. The assembly method according to claim 4, wherein
the upper part fixation bolts are made to pass through the bolt holes at both ends of the positioning jig while the positioning jig is bent to temporarily fix tip ends of the positioning jig to upper parts of the pair of the inclined column members, and
while the upper part fixation bolts used in temporary fixation are released, a bent part of the positioning jig is lifted up to make the positioning jig straight thereby to adjust the open width between the tip ends of the pair of the inclined column members and the inclination angle.

7. The assembly method according to claim 5, wherein an upper bolt out of the lower part fixation bolts fit in one of the pair of the inclined column members is made to pass through the bolt hole formed at the one end of the positioning jig, and while the opposite end of the positioning jig is free, the one end of the positioning jig is temporarily fixed to the one inclined column member, and
the inverted U shaped notch at the opposite end of the positioning jig is fit in a space between an opposite inclined column member and a nut for an upper bolt of the lower part fixation bolts fit in the opposite inclined column member thereby to adjust the open width between tip ends of the pair of the inclined column members and the inclination angle.
